(19) United States
(12) Patent Application Publication
(10) Pub. No.: US 2024/0147737 A1
(43) Pub. Date: May 2, 2024

(54) METHOD OF FABRICATING AN ELECTRONIC CHIP INCLUDING A MEMORY CIRCUIT

(71) Applicant: STMicroelectronics (Crolles 2) SAS, Crolles (FR)

(72) Inventors: Olivier WEBER, Grenoble (FR); Remy BERTHELON, Crolles (FR)

(73) Assignee: STMicroelectronics (Crolles 2) SAS, Crolles (FR)

(21) Appl. No.: 18/491,349

(22) Filed: Oct. 20, 2023

(30) Foreign Application Priority Data
Oct. 27, 2022 (FR) 2211193

(51) Int. Cl. H10B 63/00; H10B 63/10

(52) U.S. Cl. CPC H10B 63/32; H10B 63/10; H10B 63/80

(57) ABSTRACT

A method of manufacturing an electronic chip includes the following successive steps: a) forming of a first layer on top of and in contact with a second semiconductor layer, the second layer being on top of and in contact with a third semiconductor layer; b) doping of the first layer to form, on the second layer, a first doped sub-layer of the first conductivity type and a second doped sub-layer of the second conductivity type; c) forming of islands in the first layer organized in an array of rows and of columns at the surface of the second layer; and d) forming of memory cells based on a phase-change material on the islands of the first layer.

### CROSS-REFERENCE TO RELATED APPLICATION

This application claims the priority benefit of French patent application number 2211193 filed on Oct. 27, 2022, entitled “Procédé de fabrication d'une puce électronique comprenant un circuit mémoire” which is hereby incorporated by reference in its entirety.

### BACKGROUND

### Technical Field

The present disclosure is related to the field of electronic chips and, more particularly, to the field of electronic chips including a memory circuit based on a phase-change material and the corresponding manufacturing methods.

### Description of the Related Art

A phase-change material is a material having the ability to change crystal state under the effect of heat and more particularly to switch between a crystal state and an amorphous state, more strongly resistive than the crystal state. This phenomenon is used to define two memory states, for example, 0 and 1, differentiated by the resistance measured through the phase-change material.

It would be beneficial to improve electronic chips including a memory circuit including memory cells based on a phase-change material, and their manufacturing methods.

### BRIEF SUMMARY

An embodiment overcomes all or part of the disadvantages of electronic chips including a memory circuit based on a phase-change material and of their manufacturing methods.

An embodiment provides a method of manufacturing an electronic chip including the following successive steps:
a) forming of a first layer on top of and in contact with a second doped semiconductor layer of a first conductivity type, the second layer being on top of and in contact with a third doped semiconductor layer of a second conductivity type opposite to the first conductivity type;
b) doping of the first layer to form, on the second layer, a first doped sub-layer of the first conductivity type and a second doped sub-layer of the second conductivity type;
c) forming of islands in the first layer organized in an array of rows and of columns at the surface of the second layer; and
d) forming of memory cells based on a phase-change material on the islands of the first layer, the second layer, the third layer, and the second sub-layer of the first layer forming a bipolar transistor.

According to an embodiment, the method includes, after step c), an epitaxy step e) during which a fourth semiconductor layer is formed between the islands of the first layer.

According to an embodiment, the method includes, after step e), a step of doping of an area of the fourth layer of the first conductivity type.

According to an embodiment, the method includes, between steps c) and e), a step of forming of electrically-insulating spacers around the islands.

According to an embodiment, trenches are formed in the second and third layers, between said islands, in the row direction.

According to an embodiment, a memory cell is formed in front of each island.

According to an embodiment, the first layer is made of silicon.

According to an embodiment, the first layer is made of polysilicon and is formed by deposition.

According to an embodiment, said islands and memory cells are formed in a memory area of the chip, the chip further including a logic area, and at step c), are further formed, in the first layer, at the same time as the islands, gates of MOS transistors of a logic circuit.

According to an embodiment, the first layer is made of single-crystal silicon and is formed by epitaxy.

Another embodiment provides an electronic chip including islands in a first layer organized in an array of rows and of columns, the islands being arranged at the surface of a second doped semiconductor layer of a first conductivity type, itself located on top of and in contact with a third doped semiconductor layer of a second conductivity type opposite to the first conductivity type, the first layer including a first doped sub-layer of the first conductivity type, on the second layer and a second doped sub-layer of the second conductivity type, the islands being topped with memory cells based on phase-change material, the second layer, the third layer, and the second sub-layer of the first layer forming a bipolar transistor.

According to an embodiment, each island is laterally surrounded with electrically-insulating spacers.

According to an embodiment, the first layer is made of polysilicon.

According to an embodiment, the first layer is made of single-crystal silicon.

According to an embodiment, the electronic chip is formed by said method.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1A and FIG. 1B illustrate two partial and simplified cross-section views of an example of an electronic chip;

FIG. 2A and FIG. 2B illustrate two partial and simplified cross-section views of an electronic chip according to an embodiment;

FIG. 3, FIG. 4, FIG. 5, FIG. 6, FIG. 7, FIG. 8, and FIG. 9 are cross-section views illustrating steps of a method of fabricating the electronic chip illustrated in FIGS. 2A and 2B according to a first implementation mode, according to an embodiment;

FIG. 10 and FIG. 11 are cross-section views illustrating steps of a method of fabricating the electronic chip illustrated in FIGS. 2A and 2B according to a second implementation mode, according to an embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, only the steps allowing the forming of the memory circuit have been detailed hereafter, the forming of the other elements of the chip, for example, of a logic circuit located next to the memory circuit, being within the abilities of those skilled in the art.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made, unless specified otherwise, to the orientation of the figures.

Unless specified otherwise, the expressions “around”, “approximately”, “substantially” and “in the order of” signify within 10%, and preferably within 5%.

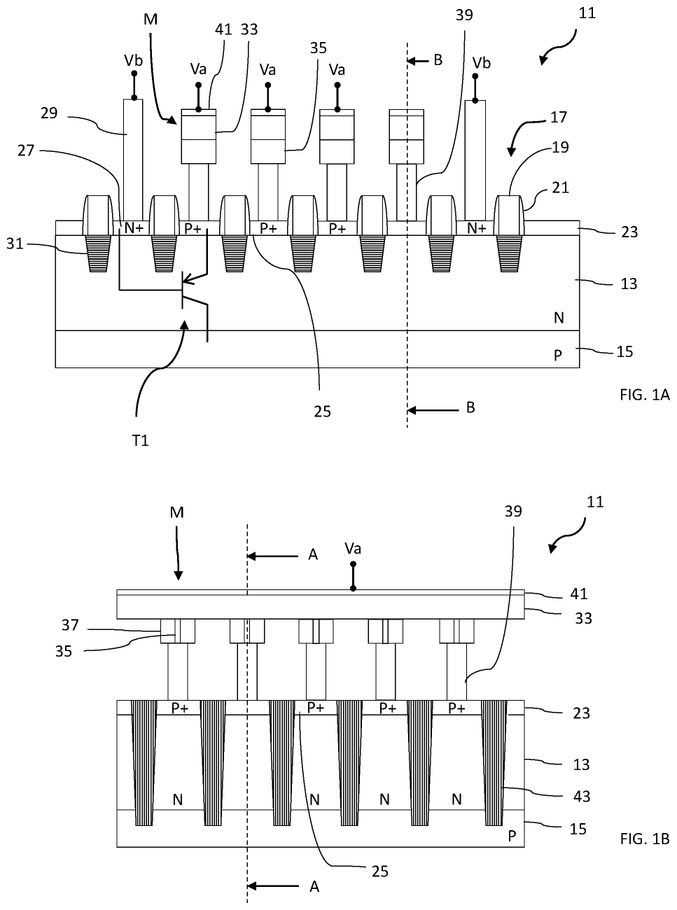

FIG. 1A and FIG. 1B illustrate two partial and simplified cross-section views of an example of an electronic chip 11, FIG. 1A being a view along the cross-section plane AA of FIG. 1B and FIG. 1B being a view along the cross-section plane BB of FIG. 1A.

More particularly, FIG. 1A and FIG. 1B illustrate a portion of electronic chip 11 and more precisely a portion of a memory circuit of electronic chip 11. As an example, electronic chip 11 includes, in a portion, not shown, a logic circuit adjacent to the memory circuit.

Electronic chip 11 includes memory cells M, for example organized, in top view, in an array of rows and of columns. As an example, the memory cells M illustrated in FIG. 1A are memory cells M of a same row while the memory cells illustrated in FIG. 1B are memory cells of a same column. It is respectively spoken of word lines and of bit lines, each memory cell M being at the intersection of a bit line and of a word line. In FIG. 1A, only four bit lines are shown and in FIG. 1B, only five word lines are shown. However, in practice, a memory circuit may include a number of bit lines and of word lines respectively different from four and five, for example, greater than four and five.

As an example, memory cells M are based on a phase-change material 33, for example, based on a chalcogenide material, for example, an alloy of germanium, antimony, and tellurium (GeSbTe) called GST. In each memory cell, the phase-change material is for example controlled by a heating resistive metal element 35 located under the phase-change material, for example in contact, by its upper phase, with the lower phase of phase-change material 33, and laterally surrounded with a thermal insulator 37. Phase-change material 33 is for example topped with metallizations 41, for example made of a conductive material. As an example, in each memory cell M, metal elements 35 and 41 respectively form a lower electrode and an upper electrode of the variable-resistance resistive element formed by phase-change material 33. As an example, the memory cells M of a same bit line are topped with a same metallization 41. In other words, the upper electrodes 41 of the memory cells M of a same bit line are interconnected. Metallizations 41 are for example coupled to nodes of application of potentials Va.

Chip 11 includes a doped semiconductor layer 13 of a first conductivity type, for example of type N, for example doped with arsenic or phosphorus atoms. Layer 13 is for example made of silicon. Layer 13 rests on a doped semiconductor layer 15 of a second conductivity type, opposite to the first conductivity type, for example of type P, for example doped with boron atoms. Layer 15 is for example made of silicon.

As an example, chip 11 includes gate patterns 17 arranged on the upper surface of layer 13, for example extending longitudinally in the bit line direction. Gate patterns 17 include, for example, a central portion 19 laterally surrounded with spacers 21. The central portion 19 of each gate pattern 17 is for example made of a semiconductor material, for example, of silicon, for example, of polysilicon. Spacers 21 are for example made of an electrically-insulating material, for example, of a silicon nitride.

In this example, gate patterns 17 extend, in top view, between the bit lines of the array of memory cells M. In other words, in this example, in top view, any two consecutive bit lines of the array of memory cells M are separated from each other by one and the same gate pattern 17 extending along the entire length of said bit lines. Gate patterns 17 are for example laterally separated by a semiconductor layer 23, for example formed by epitaxy from the upper surface of layer 13. Layer 23 is for example made of silicon, for example, of single-crystal silicon. As an example, each memory cell M is coupled, for example connected, to layer 23 by means of a via 39. As an example, via 39 is in contact, by its upper surface, with the lower surface of the heating resistive element 35 of memory cell M. Via 39 is for example in contact, by its lower surface, with the upper surface of layer 23.

Layer 23 for example includes first doped regions 25, for example, of the second conductivity type, for example, type P, and extending between certain gate patterns 17, vertically in line with the memory cells M of the array. Regions 25 are for example more heavily doped than layer 15. Each region 25 is for example topped with a memory cell. As an example, for each memory cell M, the corresponding via 39 electrically couples the heating element 35 of the memory cell to the underlying region 25.

Layer 23 further includes second doped regions 27, for example, of the first conductivity type, for example, of type N, and extending between other gate patterns 17. Regions 27 are for example more heavily doped than layer 13. Regions 27, conversely to regions 25, are for example not topped with memory cells M but with contacting vias 29. Vias 29 allow the contacting of the word lines. As an example, within a same word line, two vias 29 are spaced apart by, for example, four memory cells M (respectively belonging to four consecutive bit lines). As an example, the contacting areas are coupled to a node of application of a potential Vb applied to the concerned word line.

Regions 27 and 25 are for example laterally delimited by gate patterns 17 and by insulating trenches 31, for example, of super shallow trench insulation type (SSTI). Insulation trenches 31 prevent, for example, electric current leakages between two successive bit lines. Trenches 31 then are, for example located under gate patterns 17. As an example, trenches 31 are linear and each gate pattern is located on top of and in contact with a trench 31. As an example, each trench 31 extends longitudinally in the bit line direction, along the entire length of the bit lines. As an example, trenches 31 extend, vertically, in layer 13, from the upper surface of layer 13 across a portion only of the thickness of layer 13. Insulating trenches 31 are for example filled with a dielectric material, for example, silicon oxide. The depth of trenches 31 is for example in the range from 20 nm to 40 nm.

As an example, chip 11 includes insulating trenches 43, for example, of shallow trench insulation (STI) type. The depth of trenches 43 is for example greater than the depth of trenches 31. Trenches 43 extend, for example, from the upper surface of layer 13, in layer 13 and in a portion of layer 15. As an example, trenches 43 enable to separate and thus to electrically insulate strips of layer 13 respectively vertically in line with each word line. As an example, each trench 43 extends longitudinally in the word line direction, along the entire length of the word lines. Insulating trenches 43 are for example filled with a dielectric material, for example, silicon oxide. The depth of trenches 43 is for example in the range from 300 nm to 400 nm.

In the example of FIGS. 1A and 1B, for each memory cell M, the area 25 located vertically in line with the memory cell, layer 13 (and area 27), and layer 15 define a bipolar transistor T1, here of PNP type, for selecting the memory cell. Each memory cell MI is for example associated with a bipolar transistor T1. In this example, region 25 forms an emitter region of transistor T1, region 13 (and area 27) forms a base region of transistor T1, and layer 15 forms a collector region of transistor T1. As an example, the collector is common to all the transistors T1 of the array and is, for example, connected to ground. In this example, base region 13 is common to all the transistors T1 of a same word line of the memory circuit.

In the example of FIG. 1A, gate patterns 17 particularly have the function of respecting the constraints of surface density of gate patterns at the chip scale and of the semiconductor wafer inside and on top of which is formed the chip. These patterns do not have an electric function in the memory circuit. Gate patterns of similar structure having an electric function may however be provided in a logic circuit located on the side of the memory circuit.

The presence of gate patterns 17 within the memory circuit may however pose certain problems. For example, despite the presence of insulating trenches 31 and of spacers 21, parasitic leakage currents between gate patterns 17 and regions 25 (or 27) may exist, which may disturb the programming or the reading of memory cells M.

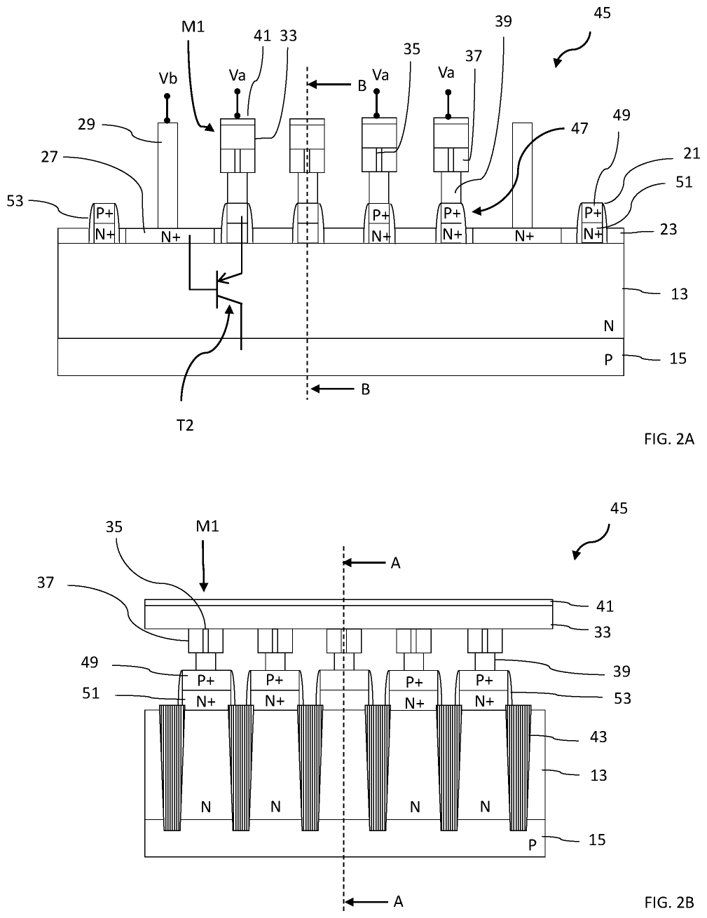

FIG. 2A and FIG. 2B illustrate two partial and simplified cross-section views of an electronic chip 45 according to an embodiment.

More particularly, FIG. 2A illustrates a view along the cross-section plane AA of FIG. 2B and FIG. 2B illustrates a view along the cross-section plane BB of FIG. 2A.

The electronic chip 45 illustrated in FIGS. 2A and 2B is similar to the chip 11 illustrated in FIGS. 1A and 1B, with the difference that the PN junction formed in FIGS. 1A and 1B by regions 25 and layer 13 is formed, in FIGS. 2A and 2B, in islands 47 at the surface of layer 13. Islands 47 substitute to the gate patterns 17 of FIGS. 1A and 1B, not present in the memory circuit of chip 45.

Electronic chip 45 thus includes islands 47, for example, parallelepipedal. Islands 47 are located at the surface of layer 13 and form a grid or array including rows and columns similar to the array of memory cells M1. Each island 47 includes a stack of a doped semiconductor layer 49 of the second conductivity type, for example, type P, and of a doped semiconductor layer 51 of the first conductivity type, for example, type N, layer 51 being on top of and in contact with layer 13 and layer 49 being on top of and in contact with layer 51. As an example, layer 49 is made of silicon. As an example, layer 51 is made of silicon. As an example, layers 51 and 49 are respectively more heavily doped than layers 15 and 13.

As an example, islands 47 are entirely laterally surrounded with spacers 53. In other words, the islands have their four sides covered with spacers 53. As an example, the spacers are made of an electrically-insulating material, for example, of silicon nitride.

The memory cells M1 of chip 45 are formed on top of and in contact with islands 47, each memory cell M1 being associated with a single island 47 and each island 47 being associated with a single memory cell M1. A memory cell M1 thus has its via 39 located on top of and in contact with layer 49.

Similarly to what has been described in relation with FIGS. 1A and 1B, islands 47 are laterally separated from one another by epitaxial layer 23 including regions 27 in front of the contacting vias 29 of the word lines. However, conversely to what has been described in relation with FIGS. 1A and 1B, layer 23 includes no regions 25 and layer 23 remains, for example, undoped, outside of regions 27.

As an example, conversely to what has been described in relation with FIGS. 1A and 1B, chip 45 includes no insulating trenches 31, thus suppressing an etch step and decreasing the fabricating costs of the electronic chip by increasing the efficiency of the fabricating method. As an example, the PN junction of layers 49 and 51 is, for each memory cell M, insulated by spacers 53.

In the embodiment of FIGS. 2A and 2B, for each memory cell M1, the layers 49 and 51 of the underlying island 47, layer 13, and layer 15 form a bipolar transistor T2 of selection of the memory cell, here of PNP type. In this example, layer 49 forms an emitter region of transistor T2, layer 49 and layer 13 form a base region of transistor T2, and layer 15 forms a collector of transistor T2. As an example, base region 13 is common to all the transistors T2 of a same word line of the memory circuit. As an example, the collector is common to all the transistors T2 of the memory circuit and is, for example, connected to a ground.

An advantage of the embodiment described in relation with FIGS. 2A and 2B is that leakage currents are decreased with respect to a chip such as illustrated in FIGS. 1A and 1B.

Another advantage of the embodiment described in relation with FIGS. 2A and 2B is that it enables to suppress insulating trenches 31, which enables to decrease the manufacturing costs of a chip.

Still another advantage of the embodiment described in relation with FIGS. 2A and 2B is that it may enable to decrease the distance between two bit lines and thus decrease the size of a chip.

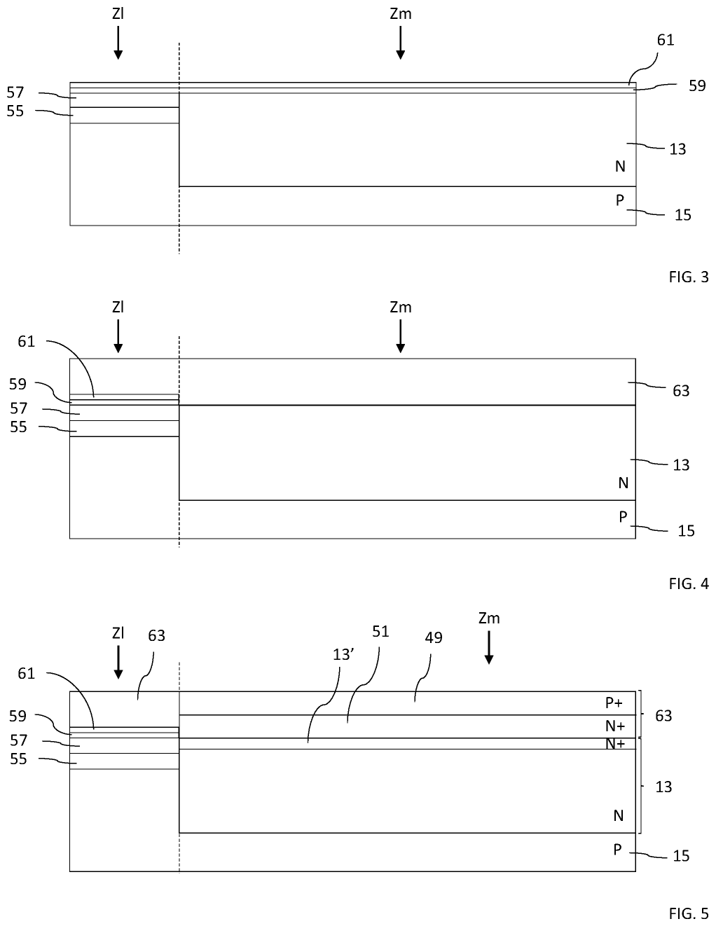

Examples of methods of fabricating such a chip will now be described in relation with FIGS. 3 to 11.

FIGS. 3 to 9 illustrate, in partial and simplified cross-section views, successive steps of a method of fabricating a chip such as illustrated in FIGS. 2A and 2B according to a first implementation mode.

FIG. 3 illustrates an initial structure including a memory area Zm, where a memory circuit is desired to be formed, and a logic area Zl, where a logic circuit including, for example, metal oxide semiconductor transistors called MOS, is desired to be formed. In FIG. 3, memory area Zm is shown on the right-hand side and logic area Zl is shown on the left-hand side.

In the following description, only the forming of the memory circuit will be detailed.

The structure illustrated in FIG. 3 includes layer 15, for example, of the second conductivity type, for example, of type p.

The structure further includes, in logic area Zl, a buried layer 55, for example, insulating, for example, made of an oxide, for example, of silicon oxide, and a layer 57, for example, semiconductor, for example, made of silicon. As an example, the stack of layers 15, 55, and 57 forms a substrate of SOI (“Silicon on Insulator”) type. In its memory area Zl, the structure includes layer 13 formed on layer 15. The memory area of the structure illustrated in FIG. 3 includes neither layer 55 nor layer 57. As an example, the plane of the upper surface of layer 13 and the plane of the upper surface of layer 57 are one and the same. As an example, logic areas Zl and memory Zm are covered with a layer 59 of a dielectric material and a conductive layer 61, layer 59 extending continuously over the entire surface of the structure, on top of and in contact with the upper surface of layers 57 and 13, and layer 61 extending over the entire surface of the structure, on top of and in contact with the upper surface of layer 59. Layer 61 is for example a conductive gate layer, for example, made of an alloy based on titanium nitride (TiN). Layer 59 is for example a gate insulator layer, for example, made of a material having a dielectric constant greater than the dielectric constant of silicon dioxide, for example, a zirconium and/or hafnium oxide, for example, of silicon dioxide, of hafnium silicide, or of hafnium silicon oxynitride.

As an example, layers 13 and 15 are made of the same material and originate from a same substrate having undergone implantations of dopants at different depths.

FIG. 4 illustrates a structure obtained at the end of a step of deposition of a semiconductor layer 63 on the upper surface of the structure illustrated in FIG. 3.

More particularly, during this step, layers 59 and 61 are first locally removed in front of memory area Zm, for example, all over the surface of memory area Zm.

The removal of layers 59 and 61 is for example performed by photolithography, followed by an etching.

During this step, layers 59 and 61 may be kept on all or part of the surface area of logic area Zl.

Layer 63 is then deposited, for example, in full wafer fashion, over the entire upper surface of the structure.

At the end of the step of deposition of layer 63, the latter covers layer 13 in memory Zm and layer 61 in logic area Zl. More particularly, in the shown example, layer 63 is in contact with the upper surface of layer 13 in memory area Zm and with the upper surface of layer 61 in logic area Zl.

Layer 63 is for example made of silicon, for example, of single-crystal silicon. As a variation, layer 63 is made of polysilicon. As an example, layer 63 has a thickness, taken in memory area Zm in front of layer 13, in the range from 20 nm to 80 nm, for example in the range from 40 nm to 50 nm.

Layer 63 in logic area is, for example, intended to form gate contacting regions of the transistors of the logic circuit.

FIG. 5 illustrates a structure obtained at the end of a step of doping of layer 63.

More particularly, during this step, a lower portion of layer 63 is doped with the first conductivity type, for example, of type N, to form layer or sub-layer 51 and an upper portion of layer 63 is doped with the second conductivity type, for example, type P, to form layer or sub-layer 49. The doping of the lower portion of layer 63 and the doping of the upper portion of layer 63 are, for example, successively carried out.

As an example, the doping of layer 63 forming layer 51 is performed before the doping of layer 61 forming layer 49.

As a variant, the doping of layer 63 forming layer 49 is performed before the doping of layer 61 forming layer 51.

The step of doping of the lower portion of layer 63 to form layer 51 generates, for example, the doping of an upper portion of layer 13 underlying layer 63, thus forming a layer or sub-layer 13′.

As an example, layers 51, 49, and 13′ are more heavily doped than layers 13 and 15.

FIG. 6 illustrates a structure obtained at the end of a step of forming of islands 47, the step of forming of islands 47 being distinct from the doping step described in relation with FIG. 5.

More particularly, during this step, there are etched in layers 49 and 51 trenches laterally delimiting islands 47. As an example, islands 47 are arranged in an array, along rows and columns. As an example, outside of islands 47, layers 49 and 51 and fully removed, the trenches etched between islands 47 emerging onto the upper surface of layer 13, for example, onto the upper surface of layer 13′. As an example, the islands are formed with a pitch, for example constant, in the range from 20 nm to 300 nm, for example in the range from 100 nm to 200 nm, for example, in the order of 118 nm. As an example, one column of islands 47 out of five is omitted (that is, etched) to leave space to the contacting vias 29 of the word lines as described in relation with FIGS. 2A and 2B.

The etching of layers 49 and 51 is for example performed by a dry etching method, for example, a conventional polysilicon etching method.

As an example, during this step, in logic area Zl, the gates of the transistors are for example also etched. The steps of etching in logic area Zl and in memory area Zm are for example carried out within a same etch step, the etch mask being adapted for the two areas.

FIG. 7 illustrates a structure obtained at the end of a step of forming of spacers 21 on the sides of islands 47, for example, along the entire periphery of islands 47.

As an example, during this step, spacers 21 are for example formed in memory area Zm simultaneously to spacers around gates of transistors in logic area Zl.

FIG. 8 illustrates a structure obtained at the end of a step of forming of layer 23. The step of forming of layer 23 is for example distinct from the step of forming of islands 47, where islands 47 are not formed of layer 23.

As an example, layer 23 is formed by epitaxy from the upper surface of layer 13, or if present of layer 13′. The step of forming of layer 23 is for example carried out after the step of forming of spacers 21. Layer 23 is for example made of silicon, for example, of single-crystal silicon.

As an example, layer 23 has a thickness in the range from 5 nm to 50 nm, for example, in the range from 10 nm to 30 nm.

FIG. 9 illustrates a structure obtained at the end of a step of local doping of layer 23.

More particularly, during this step, regions 27 are formed by local doping of layer 23. Regions 27 are for example formed by doping of the first conductivity type, for example, of type N. Region 27 is for example more heavily doped than layer 13. Regions 27 are for example formed at the location of the omitted column of islands 47, that is, each region 27 is located between four columns of islands 47.

At the end of this step, memory cells M1 are for example formed on top of and in contact with islands 47.

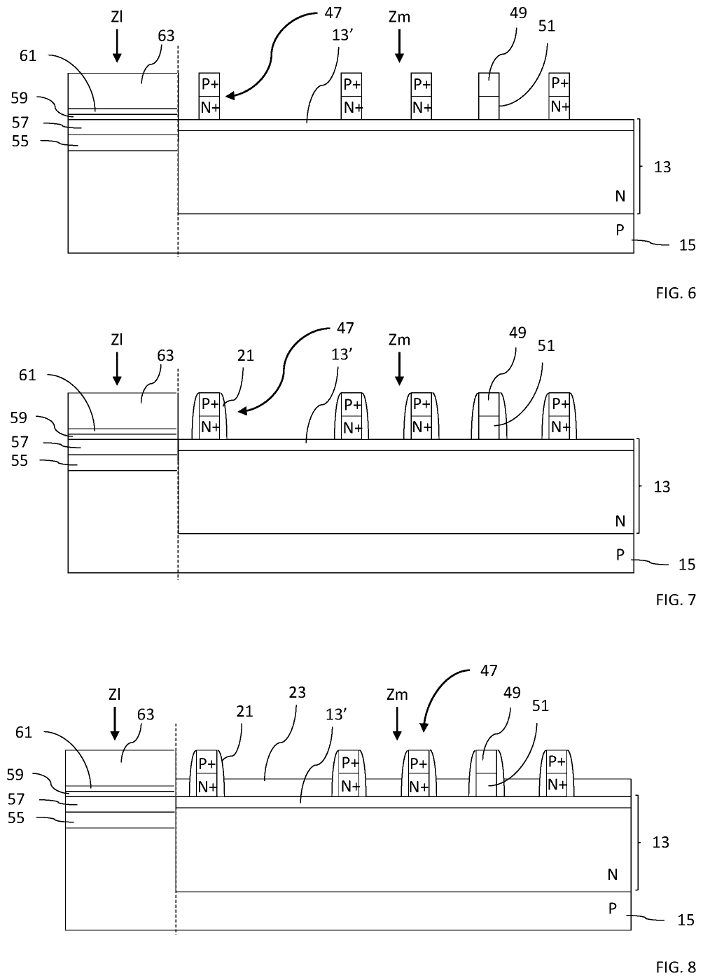

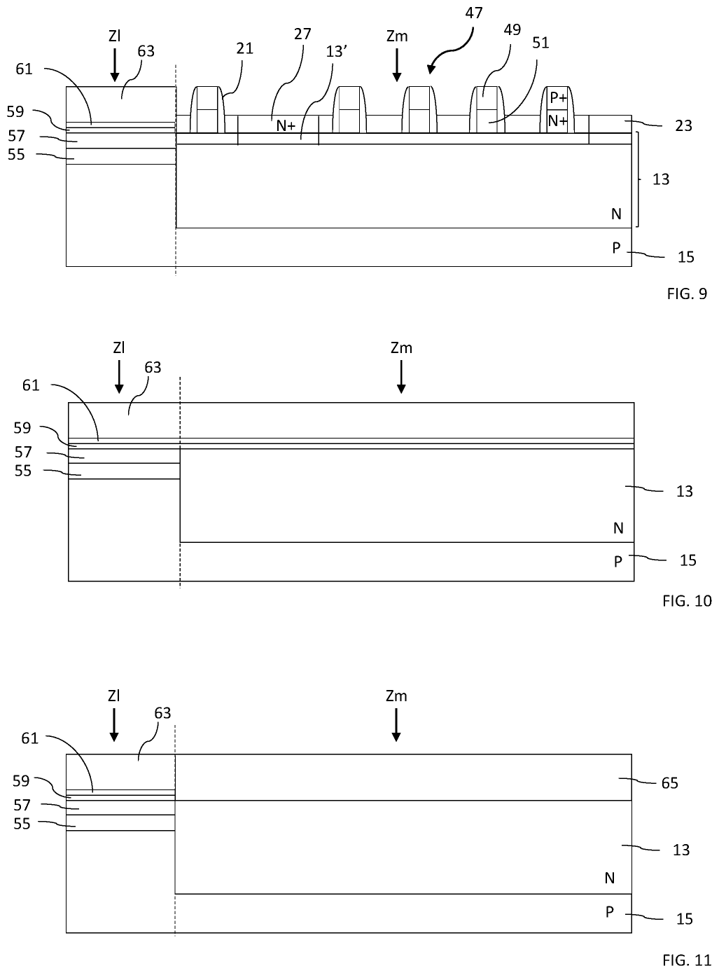

FIGS. 10 and 11 illustrate steps of a method of forming the chip illustrated in relation with FIGS. 2A and 2B according to a second implementation mode.

More particularly, the method illustrated in relation with FIGS. 10 and 11 differs from the method illustrated in relation with FIGS. 3 to 9 in that islands 47 are formed in an epitaxial layer.

FIG. 10 illustrates a structure obtained at the end of a step of forming of layer 63 on the upper surface of the structure illustrated in FIG. 3.

During this step, conversely to what has been previously described in relation with FIG. 3, layer 63 is formed over the entire upper surface of the structure, in memory area Zm and logic area Zl, with no prior removal of layers 61 and 59 from the memory area.

Layer 63 is thus in contact, by its lower surface, with the upper surface of layer 61 over the entire surface of the structure.

FIG. 11 illustrates a structure obtained at the end of a step of forming of an epitaxial layer 65.

The forming of layer 65 is for example preceded by a step of removal, from memory area Zm, of layer 63 and of layers 61 and 59. This step is for example carried out through a hard mask, for example, based on nitride. This mask enables, for example, to keep layer 63 and layers 61 and 59 in the logic area to form the gates of the MOS transistors therein. As an example, at the end of the removal step, the upper surface of layer 13 is exposed. This step is for example carried out by photolithography and etching.

After the step of removal of layers 63, 61, and 59, layer 65 is formed by epitaxy from the upper surface of layer 13. Layer 65 will thus grow in the opening left by the removal of layers 61, 59, and 63. As an example, at the end of this step, the upper surface of the formed structure is planarized so that the plane of the upper surface of layer 63 is one and the same as the plane of the upper surface of layer 65. As an example, layer 65 has a thickness in the range from 20 nm to 80 nm, for example, in the range from 40 nm to 50 nm.

The rest of the method is similar to the method described in relation with FIGS. 5 to 9. More particularly, after the steps described in relation with FIGS. 10 and 11, layer 65 is doped, islands 47 are formed, layer 23 and memory cells M1 are formed.

In this implementation mode, the doping of layer 63 includes a doping of the first conductivity type, on a lower portion, to form layer or sub-layer 51 and of the second conductivity type, on an upper portion, to form layer or sub-layer 49. Islands 47 thus include two single-crystal silicon layers 49 and 51.

An advantage of the embodiment described in relation with FIGS. 10 and 11 is that it enables to increase the quality of the materials forming the PN emitter-base junction of the selection transistor T2 of each memory cell.

Various embodiments and variants have been described. Those skilled in the art will understand that certain features of these various embodiments and variants may be combined, and other variants will occur to those skilled in the art. In particular, the described embodiments are not limited to the examples of numerical values or to the examples of materials mentioned in the present disclosure.

Finally, the practical implementation of the described embodiments and variations is within the abilities of those skilled in the art based on the functional indications given hereabove.

Electronic chip fabricating method (45), may be summarized as including the following successive steps: a) forming of a first layer (63; 65) on top of and in contact with a second doped semiconductor layer (13) of a first conductivity type (N), the second layer being on top of and in contact with a third doped semiconductor layer (15) of a second conductivity type (P) opposite to the first conductivity type; b) doping of the first layer (63; 65) to form, on the second layer, a first doped sub-layer (51) of the first conductivity type (N) and a second doped sub-layer (49) of the second conductivity type (P); c) forming of islands (47) in the first layer (63; 65) organized in an array of rows and columns at the surface of the second layer (13); and d) forming of memory cells (M1) based on a phase-change material (33) on the islands (47) of the first layer (63; 65), the second layer (13), the third layer (15), and the second sub-layer (49) of the first layer (63; 65) forming a bipolar transistor (T2).

Method may include, after step c), an epitaxy step e) during which a fourth semiconductor layer (23) is formed between the islands (47) of the first layer (63; 65).

Method may include, after step e), a step of doping of an area (27) of the fourth layer (23) of the first conductivity type (N).

Method may include, between steps c) and e), a step of forming of electrically-insulating spacers (21) around the islands (47).

Trenches (43) may be formed in the second (13) and third (15) layers, between said islands (47), in the row direction.

A memory cell (M1) may be formed in front of each island (47).

The first layer (63; 65) may be made of silicon.

The first layer (63) may be made of polysilicon and may be formed by deposition.

Said islands (47) and memory cells (M1) may be formed in a memory area (Zm) of the chip, the chip further including a logic area (Zl), and wherein, at step c), are further formed, in the first layer (63), at the same time as the islands (47), gates of MOS transistors of a logic circuit.

The first layer (65) may be made of single-crystal silicon and may be formed by epitaxy.

Electronic chip (45) may be summarized as including islands (47) in a first layer (63; 65) organized in an array of rows and of columns, the islands (47) being arranged at the surface of a second doped semiconductor layer (13) of a first conductivity type (N), itself located on top of and in contact with a third doped semiconductor layer (15) of a second conductivity type (P) opposite to the first conductivity type (N), the first layer (63; 65) including a first doped sub-layer (51) of the first conductivity type (N), on the second layer (13) and a second doped sub-layer (49) of the second conductivity type (P), the islands (47) being topped with memory cells (M1) based on a phase-change material (33), the second layer (13), the third layer (15), and the second sub-layer (49) of the first layer (63; 65) forming a bipolar transistor (T2).

Each island (47) may be laterally surrounded with electrically-insulating spacers (21).

The first layer (63) may be made of polysilicon.

The first layer (65) may be made of single-crystal silicon.

Electronic chip (45) may be formed by a method.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
forming a first layer on top of and in contact with a second doped semiconductor layer of a first conductivity type, the second layer being on top of and in contact with a third doped semiconductor layer of a second conductivity type opposite to the first conductivity type;
doping the first layer to form, on the second layer, a first doped sub-layer of the first conductivity type and a second doped sub-layer of the second conductivity type;
forming islands in the first layer organized in an array of rows and columns at the surface of the second layer; and
forming memory cells based on a phase-change material on the islands of the first layer, the second layer, the third layer, and the second sub-layer of the first layer forming a bipolar transistor.

2. The method according to claim 1, comprising forming a fourth semiconductor layer between the islands of the first layer with an epitaxial growth process.

3. The method according to claim 2, comprising doping an area of the fourth layer of the first conductivity type.

4. The method according to claim 2, comprising forming electrically-insulating spacers around the islands before forming the fourth semiconductor layer.

5. The method according to claim 1, wherein trenches are formed in the second and third layers, between the islands, in a direction of the rows.

6. The method according to claim 1, wherein a memory cell is formed in front of each island.

7. The method according to claim 1, wherein the first layer is made of silicon.

8. The method according to claim 7, wherein the first layer is made of polysilicon and is formed by deposition.

9. The method according to claim 8, wherein forming islands includes forming gates of MOS transistors of a logic circuit, wherein the islands and memory cells are formed in a memory area of the chip, the chip further including a logic area.

10. The method according to claim 7, wherein the first layer is made of single-crystal silicon and is formed by epitaxy.

11. An electronic chip, comprising:
a first doped semiconductor layer of a first conductivity type;
a second doped semiconductor layer of a second conductivity type opposite the first conductivity type on top of and in contact with the first doped semiconductor layer;
islands organized in an array of rows and of columns on the surface of the second doped semiconductor layer, each island including a first doped sub-layer of the second conductivity type on the second doped semiconductor layer and a second doped sub-layer of the first conductivity type on the first doped sub-layer;
a plurality of memory cells based on a phase-change material each on top of a respective island; and
a bipolar transistor formed of the first doped semiconductor layer, the second doped semiconductor layer, and the second doped sub-layer of the islands.

12. The electronic chip according to claim 11, wherein each island is laterally surrounded with electrically-insulating spacers.

13. The electronic chip according to claim 11, wherein the first and second doped sub-layers are made of polysilicon.

14. The electronic chip according to claim 11, wherein the first and second doped sub-layers are made of single-crystal silicon.

15. A method, comprising:
forming a first doped layer of semiconductor material of a first conductivity type;
forming a second doped layer of semiconductor material of a second conductivity type opposite to the first conductivity type on top of and in contact with the first doped layer;
forming a third doped layer on top of and in contact with the second doped layer, the third doped layer including a first doped sub-layer of the second conductivity type on the second doped layer and a second doped sub-layer of the first conductivity type on the first doped sub-layer;
patterning the third doped layer to form a plurality of islands arranged in rows and columns on the second doped layer;
surrounding each island with a respective electrically insulating spacer;
forming a layer of semiconductor material between the islands after forming the electrically insulating spacers; and
forming a plurality of phase-change memory cells each on top of a respective island, a bipolar transistor being formed of the first doped layer, the second doped layer, and the second doped sub-layer of the islands.

16. The method of claim 15, comprising forming the layer of semiconductor material between the islands with an epitaxial growth process from the second doped layer.

17. The method of claim 15, comprising doping an area of the layer of semiconductor material with the first conductivity type.

18. The method of claim 15, wherein the first and second doped sub-layers are made of polysilicon.

19. The method of claim 15, wherein the first and second doped sub-layers are made of single-crystal silicon.

20. The method of claim 15, comprising forming trenches in the first doped layer and the second doped layer, between the islands, in a direction of the rows.
